(19) United States
(12) Patent Application Publication
(10) Pub. No.: US 2026/0026380 A1
(43) Pub. Date: Jan. 22, 2026

(54) ELECTRONIC DEVICE AND MANUFACTURING METHOD THEREOF

(71) Applicant: InnoLux Corporation, Miao-Li County (TW)

(72) Inventors: Chia-Ping TSENG, Miao-Li County (TW); Hung-Wen LI, Miao-Li County (TW)

(21) Appl. No.: 19/243,770

(22) Filed: Jun. 20, 2025

Related U.S. Application Data
(60) Provisional application No. 63/673,175, filed on Jul. 19, 2024.

(30) Foreign Application Priority Data
Mar. 17, 2025 (CN) 202510308101.3

(51) Int. Cl. H01L 23/498; H01L 21/48; H01L 21/66; H01L 25/16

(52) U.S. Cl. CPC H01L 23/49838; H01L 21/486; H01L 22/26; H01L 23/49827; H01L 25/162

(57) ABSTRACT

An electronic device and a manufacturing method thereof are disclosed. The manufacturing method of the electronic device includes: providing a substrate having a first surface and a second surface opposite to the first surface; forming a through hole penetrating the substrate, a side wall of the through hole connected with the first surface and the second surface; providing a first conductive layer on the substrate, the first conductive layer extending into the through hole; providing a second conductive layer on the first conductive layer, the second conductive layer extending into the through hole and having an original thickness; performing a thinning step to remove at least a portion of the second conductive layer; and performing an inspection step to obtain a first inspection result, and determining whether to continue subsequent steps according to the first inspection result.

### CROSS REFERENCE TO RELATED APPLICATION

This application claims the benefit of U.S. Provisional Application No. 63/673,175, filed on Jul. 19, 2024. The content of the application is incorporated herein by reference.

### BACKGROUND OF THE DISCLOSURE

### 1. Field of the Disclosure

The present disclosure relates to an electronic device and a manufacturing method thereof, and more particularly to a manufacturing method of an electronic device including forming a through hole in the substrate and an electronic device manufactured by the method.

### 2. Description of the Prior Art

In the existing electronic device, a through hole may be formed in the substrate, and a conductive material is disposed in the through hole to serve as a conducting wire for transmitting an electrical signal. However, as the size of the through hole becomes smaller and smaller, and the depth-width ratio and density thereof become higher and higher, the stress matching problem easily occurs between the layers formed on the substrate due to the different thermal expansion coefficients of their constituent materials, which may cause the substrate to crack after being heated during the manufacturing process, or result in poor product reliability or yield.

### SUMMARY OF THE DISCLOSURE

One of objectives of the present disclosure is to provide a manufacturing method of an electronic device and an electronic device manufactured by the method, wherein by performing a thinning step during the manufacturing process to remove at least a portion of a conductive layer formed on a substrate, the stress matching problem between layers may be alleviated.

The present disclosure provides a manufacturing method of an electronic device. The method includes: providing a substrate, wherein the substrate has a first surface and a second surface opposite to the first surface; forming a through hole penetrating the substrate, wherein a side wall of the through hole is connected with the first surface and the second surface; providing a first conductive layer on the substrate, wherein the first conductive layer extends into the through hole; providing a second conductive layer on the first conductive layer, wherein the second conductive layer extends into the through hole, and the second conductive layer has an original thickness; performing a thinning step to remove at least a portion of the second conductive layer; and performing an inspection step to obtain a first inspection result, and determining whether to continue subsequent steps according to the first inspection result.

The present disclosure provides an electronic device. The electronic device includes a substrate, a first conductive pattern layer; a second conductive pattern layer and a redistribution structure. The substrate has a first surface, a second surface and a through hole, and a side wall of the through hole is connected with the first surface and the second surface. The first conductive pattern layer is disposed on the side wall. The second conductive pattern layer is disposed on the first conductive pattern layer. The redistribution structure is disposed on the first conductive pattern layer and the second conductive pattern layer. The second conductive layer has a third surface adjacent to the first surface, and a maximum height difference between the first surface and the third surface in a normal direction of the substrate is greater than or equal to 0.1 micrometers and less than or equal to 20 micrometers.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a flowchart of a manufacturing method of an electronic device according to an embodiment of the present disclosure.

FIG. 2 to FIG. 5 are schematic diagrams illustrating a portion of the process of a manufacturing method of an electronic device according to an embodiment of the present disclosure.

FIG. 6 is a cross-sectional schematic diagram of an electronic device according to an embodiment of the present disclosure.

FIG. 7 is a cross-sectional schematic diagram of an electronic device according to another embodiment of the present disclosure.

FIG. 8A is a top-view perspective schematic diagram illustrating a partial process of an electronic device according to another embodiment of the present disclosure.

FIG. 8B is a cross-sectional schematic diagram illustrating the partial process of the electronic device of FIG. 8A.

FIG. 9 to FIG. 11 are schematic diagrams illustrating a portion of the process of a manufacturing method of an electronic device according to another embodiment of the present disclosure.

FIG. 12 to FIG. 14 are schematic diagrams illustrating a portion of the process of a manufacturing method of an electronic device according to still another embodiment of the present disclosure.

FIG. 15 and FIG. 16 are schematic diagrams illustrating a portion of the process of a manufacturing method of an electronic device according to yet another embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device or structure, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. The present disclosure does not intend to distinguish between components that differ in name but not function. In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The term “connect” referred to in the present disclosure may refer to a physical connection or electrical connection, including connecting methods of direct or indirect contact. The term “disposed on . . . ” referred to in the present disclosure is used to describe the relative position relationship of elements, and is not intended to limit the steps or sequence of the manufacturing process thereof. The term “surround” referred in the present disclosure may mean that in a cross-sectional view of the electronic device, at least a portion of the surrounded element or layer is disposed within another element or layer, and the another element or layer may further contact the side surface of the corresponding surrounded element or layer in some embodiments.

The directional terms mentioned in the present disclosure, such as “up”, “down”, “front”, “back”, “left”, “right”, etc., are only directions referring to the drawings. Therefore, the directional terms used are for illustration, not for limitation of the present disclosure.

In the present disclosure, when an element is referred to as being “disposed on” another element, it is not intended to limit the steps or sequence of forming the element and the another element. Furthermore, in the present disclosure, when an element is referred to as being “disposed on” another element, it may also include the element is formed on a sidewall of the another element.

In the present disclosure, the term “about”, “substantially”, “approximately” or “the same” generally mean being within 20%, 10%, 5%, 3%, 2%, 1% or 0.5% of a given value or range. The quantities given herein are approximate, meaning that even in the absence of explicit qualifiers such as “about”, “substantially”, “approximately” or “identical”, such meanings may still be implied.

The term “between a value A and a value B” is interpreted as including the value A and the value B or including at least one of the value A and the value B, and including other values between the value A and the value B.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

In the present disclosure, the depth, thickness, length, width, crystallinity and/or hole diameter may be measured by using an X-ray diffractometer (XRD), an optical microscope (OM), an electron microscope (such as a scanning electron microscope (SEM), a transmission electron microscope (TEM), etc.) or other methods, but not limited herein.

In the present disclosure, the roughness may be determined by observing through a SEM. On an uneven surface, it may be seen that a height difference of 0.15 micrometers (μm) to 1 micrometer exists between the peaks and the valleys of the surface. The measurement of the roughness determination may include observing surface undulations using instruments such as a SEM, a TEM and the like at the same appropriate magnification, and taking a sample with a unit length (e.g., 10 μm) to compare the undulation condition as its roughness range. The term “appropriate magnification” described above refers to a magnification at which at least 10 undulating peaks of a roughness (Rz) or an average roughness (Ra) of at least one surface can be seen within the field of view.

The electronic device of the present disclosure may be a semiconductor package device and may be applied to any device. The electronic device may include, for example, a display device, a light-emitting device, a sensing device, an antenna device, a touch device, a tiled device, a package device or other suitable devices, but not limited herein. The electronic device may be a bendable electronic device, a stretchable electronic device, a foldable electronic device, a rollable electronic device and/or a flexible electronic device, but not limited herein. The display device may for example be applied to laptops, common displays, tiled displays, vehicle displays, touch displays, televisions, monitors, smart phones, tablets, light source modules, lighting devices, military equipment or electronic devices applied to the products mentioned above, but not limited herein. The sensing device may be a sensing device used for sensing capacitance variation, light, heat or ultrasonic waves, but not limited herein. The sensing device may include, for example, a biosensor, a touch sensor, a fingerprint sensor, other suitable sensors or combinations of the above sensors. The display device may include, for example, liquid crystal molecules, light emitting diodes, fluorescent material, phosphors, other suitable display media or combinations of the above, but not limited herein. The light-emitting diode may include an organic light-emitting diode (OLED), a mini light-emitting diode (mini LED), a micro light-emitting diode (micro LED), a quantum dot light-emitting diode (such as QLED or QDLED), other suitable materials or any arrangement and combination of the above materials, but not limited herein. The antenna device may for example include a liquid crystal antenna device, a varactor diode antenna device or other types of antenna devices, but not limited herein. The tiled device may for example include a tiled display device or a tiled antenna device, but not limited herein. In addition, the outline of the electronic device may be a rectangle, a circle, a polygon, a shape with curved edge, curved or other suitable shapes. The electronic device may include peripheral systems such as a driving system, a controlling system, a light source system, a shelving system, and the like. The electronic device may include electronic units, wherein the electronic units may include passive elements and/or active elements, such as capacitors, resistors, inductors, diodes, transistors, sensors, and the like. It should be noted that the electronic device of the present disclosure may be combinations of the above devices, but not limited herein.

The manufacturing method of the electronic device of the present disclosure may for example be applied to a wafer-level package (WLP) process or a panel-level package (PLP) process, wherein the WLP process or the PLP process may include a chip-first process or a chip-last process, but not limited herein. The electronic device of the present disclosure may be for example applied to a power module, a semiconductor package device, a display device, a light-emitting device, a backlight device, an antenna device, a sensing device or a tiled device, but not limited herein. The electronic device may include the system on a chip (SoC), system in a package (SiP), antenna in package (AiP), co-packaged optics (CPO) or combinations of the above devices, but not limited herein.

It should be noted that the technical features in different embodiments described in the following can be replaced, recombined, or mixed with one another to constitute another embodiment without departing from the spirit of the present disclosure.

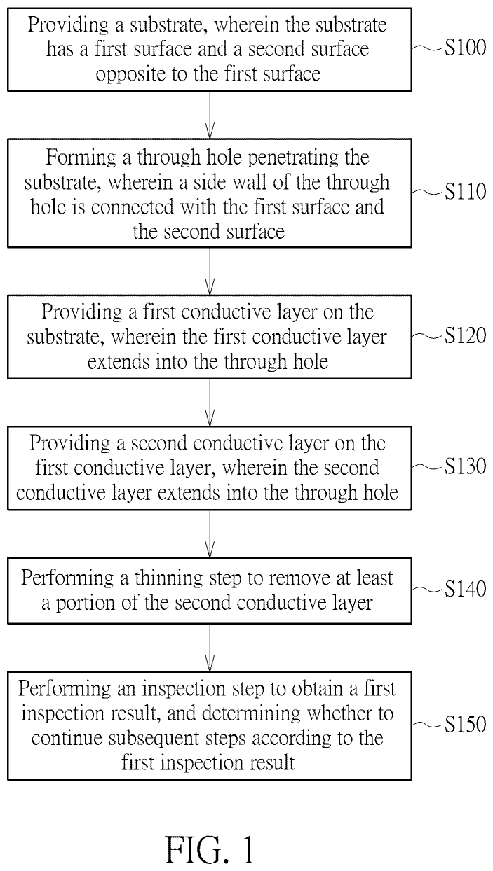

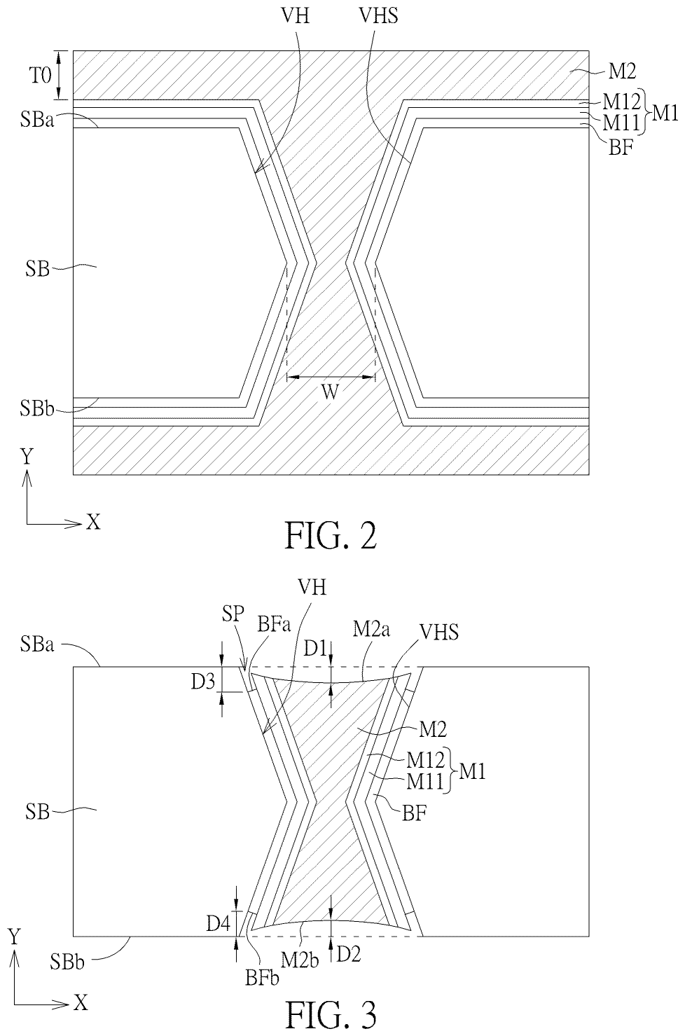

Please refer to FIG. 1 and FIG. 2 to FIG. 5. FIG. 1 is a flowchart of a manufacturing method of an electronic device according to an embodiment of the present disclosure. FIG. 2 to FIG. 5 are schematic diagrams illustrating a portion of the process of a manufacturing method of an electronic device according to an embodiment of the present disclosure. As shown in FIG. 1, a manufacturing method of an electronic device according to an embodiment of the present disclosure may include the following steps:
Step S100: providing a substrate, wherein the substrate has a first surface and a second surface opposite to the first surface;
Step S110: forming a through hole penetrating the substrate, wherein a side wall of the through hole is connected with the first surface and the second surface;
Step S120: providing a first conductive layer on the substrate, wherein the first conductive layer extends into the through hole;
Step S130: providing a second conductive layer on the first conductive layer, wherein the second conductive layer extends into the through hole, and the second conductive layer has an original thickness;
Step S140: performing a thinning step to remove at least a portion of the second conductive layer; and
Step S150: performing an inspection step to obtain a first inspection result, and determining whether to continue subsequent steps according to the first inspection result.

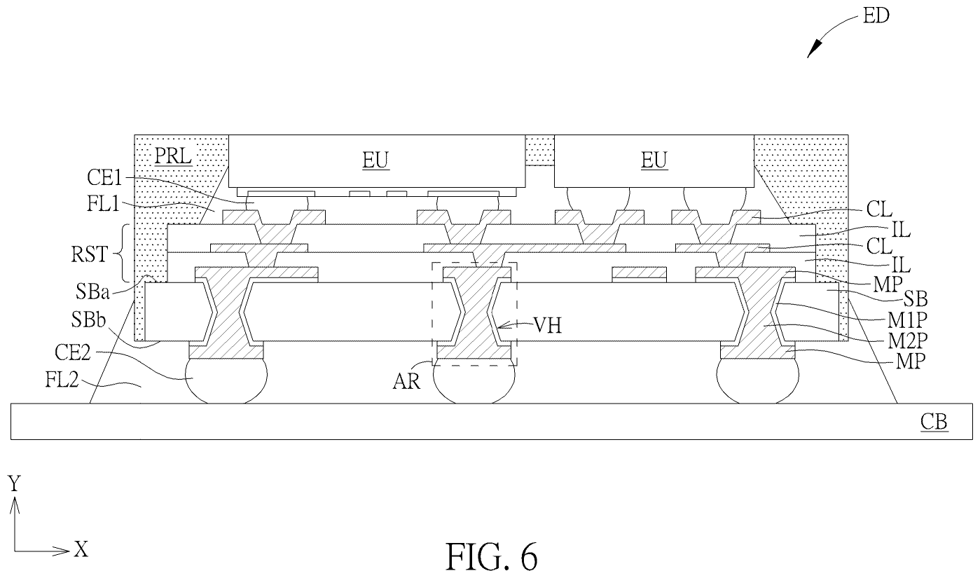

Specifically, as shown in FIG. 2, first, Step S100 may be performed to provide a substrate SB, wherein the substrate SB has an upper surface SBa (which may be referred to as a first surface) and a lower surface SBb (which may be referred to as a second surface) opposite to the upper surface SBa. The substrate SB may include a glass substrate, a transparent material including silicon, an optical layer, an acrylic board, a semiconductor structure substrate, combinations of the above or other transparent materials, and the substrate SB may have certain stiffness and insulation. That is to say, the stiffness of the substrate SB may be greater than the stiffness of a circuit structure (such as the redistribution structure RST shown in FIG. 6) formed on the substrate SB, for example, the stiffness of the substrate SB is greater than the stiffness of an insulating layer of the circuit structure, so that the warpage may be mitigated when the substrate SB is used for carrying the circuit structure, but not limited herein. The “stiffness” referred to in the present disclosure may be tested by a universal testing machine (UTM). In some embodiments, the thermal expansion coefficient of the substrate SB may be greater than or equal to 1 ppm/° C. and less than or equal to 10 ppm/° C., thereby improving the support of the substrate SB or further improving the reliability of the electronic device. In some embodiments, the transmittance of the substrate SB for visible light may be at least greater than or equal to 80%.

After Step S100, Step S110 may be performed to form a through hole VH penetrating the substrate SB, wherein a side wall VHS of the through hole VH is connected with the upper surface SBa and the lower surface SBb of the substrate SB. For example, one or more through holes VH may be formed in the substrate SB by performing a modification process and an etching process on the substrate SB. Specifically, a modification process (e.g., a laser modification process) may be performed on a portion of the substrate SB, wherein the portion of the substrate SB may correspond to a predetermined disposing position of the through hole VH. After the modification process, an etching process (e.g., a dry etching process or a wet etching process) may be selected to be performed on the substrate SB to remove the modified portion of the substrate SB, thereby forming one or more through holes VH penetrating the substrate SB. In some embodiments, in a cross-sectional view, the shape of the formed through hole VH may be an hourglass shape, a rectangle, a trapezoid, an inverted trapezoid, or other suitable shapes. In the present disposure, an hourglass shape is used as an example for illustration.

After Step S110, Step S120 may be performed to provide or form a first conductive layer M1 on the substrate SB, wherein the first conductive layer M1 further extends into the through hole VH, and the first conductive layer M1 may be a seed layer, which may conduce to the subsequent formation of a second conductive layer M2 and/or improve the adhesion between the layers. Specifically, the first conductive layer M1 may be disposed on the upper surface SBa and the lower surface SBb of the substrate SB and the side wall VHS of the through hole VH. The manufacturing process of the first conductive layer M1 may include atomic layer deposition (ALD), physical vapor deposition (PVD), chemical vapor deposition (CVD), sputtering, coating, other suitable deposition processes or combinations of the above. In some embodiments, the first conductive layer M1 may be a composite layer, for example, composed of a first sub-layer M11 and a second sub-layer M12. Specifically, the first sub-layer M11 may be formed on the upper surface SBa and the lower surface SBb of the substrate SB and the side wall VHS of the through hole VH, and then the second sub-layer M12 may be formed on the first sub-layer M11 to extend into the through hole VH, so that the first sub-layer M11 and the second sub-layer M12 are formed on the upper surface SBa and the lower surface SBb of the substrate SB and the side wall VHS of the through hole VH in sequence. The material of the first sub-layer M11 includes, for example, titanium (Ti), titanium nitride (TiN), ruthenium (Ru), tantalum (Ta), silver (Ag) or combinations of the above materials. The first sub-layer M11 may conduce to improving the bonding strength between metal material and inorganic material, i.e., may improve the adhesion between the layers, and the first sub-layer M11 may further be used as a barrier layer to block electron migration. The material of the second sub-layer M12 includes, for example, copper (Cu), and the second sub-layer M12 may conduce to the formation of the second conductive layer M2 thereon in the subsequent processes. However, the structure of the first conductive layer M1 of the present disclosure is not limited to the above, and in other embodiments, the first conductive layer M1 may be a single-layer structure or other suitable multi-layer structures. According to some embodiments, a thickness of the first sub-layer M11 and a thickness of the second sub-layer M12 may range from 50 nm to 1000 nm, respectively, and the thicknesses of the first sub-layer M11 and the second sub-layer M12 may gradually become thinner from the upper surface SBa and the lower surface SBb of the substrate SB to the center of the through hole VH, but not limited herein.

In some embodiments, as shown in FIG. 2, a buffer layer BF may be optionally provided or formed on the substrate SB before forming the first conductive layer M1 (i.e., before performing Step S120), so that the buffer layer BF covers the upper surface SBa and the lower surface SBb of the substrate SB and the side wall VHS of the via hole VH. Then, the first conductive layer M1 is blanketly formed on the surface of the buffer layer BF. In a direction X, a ratio of a thickness of the buffer layer BF at the center of the through hole VH to a minimum width W of the through hole VH may be 0.02 to 0.2, so that the risk of the substrate SB being broken may be reduced. The direction X may be perpendicular to a direction Y and may be, for example, a horizontal direction, the direction Y is a normal direction of the substrate SB, i.e., the direction Y may be parallel to a normal direction or a top-view direction of the upper surface SBa (or the lower surface SBb) of the substrate SB and may be a normal direction of the manufactured electronic device. The center of the through hole VH mentioned in the present disclosure is the position where the width of the through hole VH is the smallest in the direction X, i.e., the position corresponding to the smallest width W. In some embodiments, the buffer layer BF may be a composite structure, for example, including a first buffer layer and a second buffer layer, and the first buffer layer is disposed between the substrate SB and the second buffer layer, wherein the materials of the first buffer layer and the second buffer layer may be the same or different. For example, the first buffer layer may include organic material, and the second buffer layer may include organic material or inorganic material, but not limited herein. According to some embodiments, the buffer layer BF may further include a third buffer layer and a fourth buffer layer, wherein the third buffer layer may include organic material, and the fourth buffer layer may include organic material or inorganic material, but not limited herein.

As shown in FIG. 2, after Step S120, Step S130 may be performed to provide or form a second conductive layer M2 on the first conductive layer M1, wherein the second conductive layer M2 extends into the through hole VH, and the second conductive layer M2 has an original thickness T0. Specifically, the second conductive layer M2 may be formed on the first conductive layer M1 and in the through hole VH by, for example, electroplating, electroless plating, sputtering or other suitable processes, so that the second conductive layer M2 is located on the upper surface SBa and the lower surface SBb of the substrate SB and filled in the through hole VH. The original thickness T0 may be obtained by measuring the thickness of the second conductive layer M2 on the upper surface SBa or the lower surface SBb of the substrate SB along the direction Y, i.e., a portion of the second conductive layer M2 located on the upper surface SBa of the substrate SB is overlapped with the upper surface SBa in the direction Y and the thickness thereof may be defined as the original thickness T0, or a portion of the second conductive layer M2 located on the lower surface SBb of the substrate SB is overlapped with the lower surface SBb in the direction Y and the thickness thereof may be defined as the original thickness T0. The material of the second conductive layer M2 includes, for example, copper (Cu), titanium (Ti), aluminum (Al), molybdenum (Mo), nickel (Ni), ruthenium (Ru), tantalum (Ta), tungsten (W), other suitable conductive materials or combinations of the above materials. The thermal expansion coefficient of the second conductive layer M2 may be, for example, greater than or equal to 10 ppm/° C. and less than or equal to 30 ppm/° C.

As shown in FIG. 3, after Step S130, Step S140 may be performed to perform a thinning step to remove at least a portion of the second conductive layer M2. The thinning step may include one or both of the chemical mechanical polishing process and the wet etching process. Specifically, in the thinning step of the embodiment shown in FIG. 3, a portion of the buffer layer BF, a portion of the first conductive layer M1 and a portion of the second conductive layer M2 may be removed, so that the layer-stack located on the upper surface SBa and the lower surface SBb of the substrate SB is removed, and the upper surface SBa and the lower surface SBb are exposed. In some embodiments, the method of removing the portion of the buffer layer BF is different from the method of removing the portion of the second conductive layer M2. For example, the portion of the buffer layer BF may be removed through the wet etching process, and the portion of the second conductive layer M2 may be removed through the chemical mechanical polishing process, i.e., the thinning step may include the chemical mechanical polishing process and the wet etching process, but not limited herein. In some embodiments, the portion of the first conductive layer M1 may be removed by the wet etching process. In other embodiments, the portion of the buffer layer BF, the portion of the first conductive layer M1 and the portion of the second conductive layer M2 may all be removed by the chemical mechanical polishing process, but not limited herein.

According to the embodiment shown in FIG. 3, after removing the portion of the second conductive layer M2 through the thinning step (i.e., Step S140), the second conductive layer M2 has an upper surface M2a (which may be referred to as a third surface) and a lower surface M2b opposite to the upper surface M2a. The upper surface M2a is adjacent to the upper surface SBa of the substrate SB, i.e., the upper surface M2a of the second conductive layer M2 is closer to the upper surface SBa of the substrate SB than the lower surface M2b, and the lower surface M2b of the second conductive layer M2 is adjacent to the lower surface SBb of the substrate SB. Further, after removing the portion of the second conductive layer M2 through the thinning step, the second conductive layer M2 located in the through hole VH may occupy 75% to 98% of an accommodation space of the through hole VH, or 80% to 95%, or 83% to 93%, wherein the accommodation space of the through hole VH is the size of the space occupied by the through hole VH between the upper surface SBa and the lower surface SBb of the substrate SB. In the direction Y, a maximum height difference D1 between the upper surface SBa of the substrate SB and the upper surface M2a of the second conductive layer M2 may be greater than or equal to 0.1 micrometers and less than or equal to 20 micrometers. In addition, in the direction Y, a maximum height difference D2 between the lower surface SBb of the substrate SB and the lower surface M2b of the second conductive layer M2 may be greater than or equal to 0.1 micrometers and less than or equal to 20 micrometers. In a cross-sectional view, the maximum height difference D1 may be obtained by measuring the maximum distance between the plane where the upper surface SBa of the substrate SB is located and the upper surface M2a of the second conductive layer M2 along the direction Y, and the maximum height difference D2 may be obtained by measuring the maximum distance between the plane where the lower surface SBb of the substrate SB is located and the lower surface M2b of the second conductive layer M2 along the direction Y. As shown in FIG. 3, the upper surface M2a and the lower surface M2b of the second conductive layer M2 may be recessed with respect to the upper surface SBa and the lower surface SBb of the substrate SB, respectively, and the upper surface M2a and the lower surface M2b may be a concave surface. In some embodiments, after removing the portion of the first conductive layer M1 and the portion of the second conductive layer M2 through the thinning step (i.e., Step S140), the upper surface M2a of the second conductive layer M2 and the upper surface of the first conductive layer M1 may jointly form a continuous or discontinuous concave surface, and the lower surface M2b of the second conductive layer M2 and the lower surface of the first conductive layer M1 may jointly form a continuous or discontinuous concave surface, but not limited herein.

According to the embodiment shown in FIG. 3, after removing the portion of the buffer layer BF through the thinning step (i.e., Step S140), the buffer layer BF has an upper surface BFa (which may be referred to as a fourth surface) and a lower surface BFb opposite to the upper surface BFa. The upper surface BFa is adjacent to the upper surface SBa of the substrate SB, i.e., the upper surface BFa of the buffer layer BF is closer to the upper surface SBa of the substrate SB than the lower surface BFb, and the lower surface BFb of the buffer layer BF is adjacent to the lower surface SBb of the substrate SB. In the direction Y, a maximum height difference D3 between the upper surface SBa of the substrate SB and the upper surface BFa of the buffer layer BF may be greater than or equal to 0.5 micrometers and less than or equal to 20 micrometers. Furthermore, in the direction Y, a maximum height difference D4 between the lower surface SBb of the substrate SB and the lower surface BFb of the buffer layer BF may be greater than or equal to 0.5 micrometers and less than or equal to 20 micrometers. The measuring methods of the maximum height difference D3 and the maximum height difference D4 may be referred to the maximum height difference D1 and the maximum height difference D2 described above, which will not be redundantly described herein. As shown in FIG. 3, due to the difference in etching rates between materials, the maximum height difference D3 may be greater than the maximum height difference D1, and the maximum height difference D4 may be greater than the maximum height difference D2. That is to say, the upper surface BFa and the lower surface BFb of the buffer layer BF may be more concave than the upper surface M2a and the lower surface M2b of the second conductive layer M2, respectively, so that a space SP is formed between the side wall VHS of the through hole VH and the first conductive layer M1. In some embodiments, the upper surface BFa and the lower surface BFb of the buffer layer BF may be a concave surface, respectively, but not limited herein.

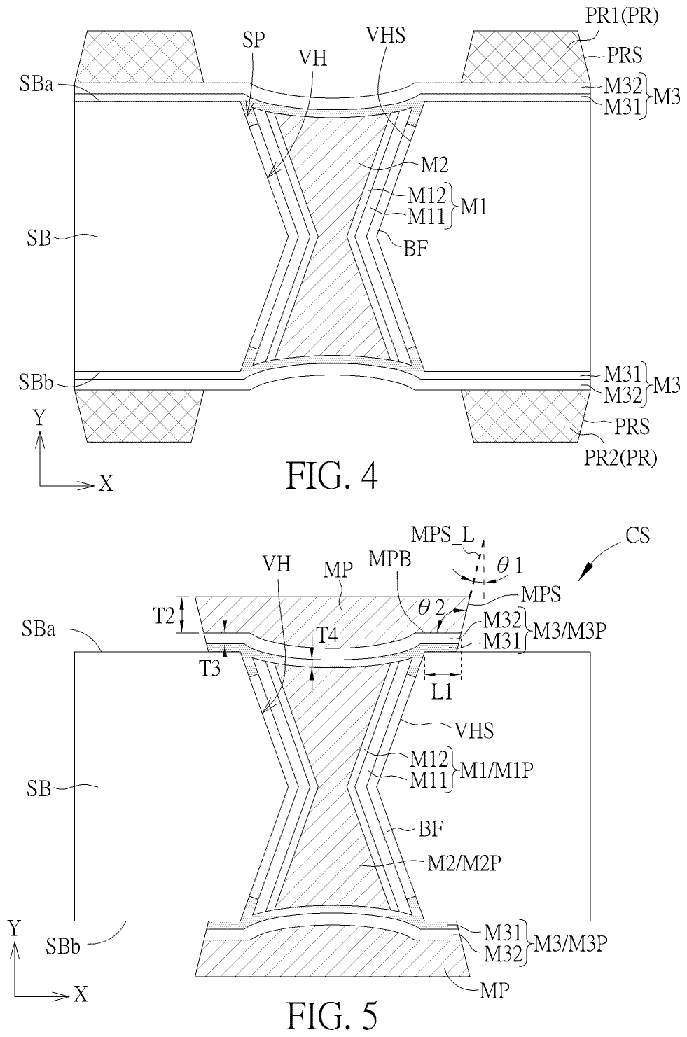

After Step S140, Step S150 may be performed to perform an inspection step to obtain a first inspection result, and determine whether to continue subsequent steps according to the first inspection result. Please refer to FIG. 4, according to the first inspection result, it may be determined whether to form a conductive pattern layer MP (shown in FIG. 5) on the second conductive layer M2. Specifically, the formed structure (as shown in FIG. 3) may be inspected after the thinning step to obtain the first inspection result. Wherein, the first inspection result may include a thinned thickness T1 of the second conductive layer M2 on the upper surface SBa (or the lower surface SBb) of the substrate SB in the direction Y, and the conductive pattern layer MP may be formed on the second conductive layer M2 when the thinned thickness T1 is less than or equal to half of the original thickness T0 (shown in FIG. 2) (i.e., when T1≤T0*½). The thinned thickness T1 herein may represent a thickness of the second conductive layer M2 on any surface (i.e., the upper surface SBa or the lower surface SBb) of the substrate SB. According to the embodiment shown in FIG. 3, the portion of the second conductive layer M2 on the upper surface SBa and the lower surface SBb of the substrate SB have been removed, i.e., the thinned thickness T1 of the second conductive layer M2 on the upper surface SBa (or the lower surface SBb) of the substrate SB is 0 (thus not labeled in FIG. 3), at this time the thinned thickness T1 is less than half of the original thickness T0, and it is determined to continue the processes of forming the conductive pattern layer MP as shown in FIG. 4 and FIG. 5 according to this inspection result. When the thinned thickness T1 is greater than half of the original thickness T0 (i.e., when T1>T0*½), another thinning step may be performed to further thin the thickness of the portion of the second conductive layer M2 on the upper surface SBa and the lower surface SBb of the substrate SB. In some embodiments, the first inspection result may further include the maximum height difference D1 being greater than or equal to 0.1 micrometers and less than or equal to 20 micrometers and/or the maximum height difference D2 being greater than or equal to 0.1 micrometers and less than or equal to 20 micrometers. When the maximum height difference D1 (and/or the maximum height difference D2) is 0.1 micrometers to 20 micrometers, it is determined to continue the processes of forming the conductive pattern layer MP as shown in FIG. 4 and FIG. 5, and when the maximum height difference D1 (and/or the maximum height difference D2) exceeds the above range, another thinning step may be performed to further reduce the thickness of the second conductive layer M2, and then the conductive pattern layer MP may be formed. Further, when the inspection step is performed by an inspection device, the inspection device may provide light waves, sound waves, electromagnetic waves, microwaves or other waves that is capable of passing through the conductive layer, the insulating layer or the layer required to be detected, so as to perform the inspection step. For example, the inspection device may have at least one light source, which may provide light with a wavelength of 400 nanometers to 1700 nanometers.

According to the manufacturing method of the electronic device described in the above embodiments, the portion of the buffer layer BF, the portion of the first conductive layer M1 and the portion of the second conductive layer M2 are removed through the thinning step in the manufacturing process, so as to thin the layer-stacking structure on the substrate SB, such that the stress matching problem between the layers may be alleviated, thereby reducing the probability that the substrate SB is cracked or the layer is peeled off when the conductive pattern layer MP is subsequently formed or the circuit is continuously formed on the conductive pattern layer MP, and further improving the yield and reliability of the electronic device. Furthermore, since the corners where the side wall VHS of the through hole VH is in contact with the upper surface SBa or the lower surface SBb of the substrate SB are more likely to cause the problem of stress mismatch, which leads to the fracture of the substrate SB, the manufacturing method of the present disclosure makes the second conductive layer M2 with large thermal expansion coefficient concave relative to the surface of the substrate SB without being in contact with the above corners through the thinning step, so that the probability of the substrate SB being cracked may be reduced. In addition, a portion of the buffer layer BF, a portion of the first conductive layer M1 and a portion of the second conductive layer M2 are still disposed in the through hole VH after the thinning step, and these layers may achieve the function of buffering the crack.

When it is determined to continue to form the conductive pattern layer MP on the second conductive layer M2 according to the first inspection result, the following steps may be performed. As shown in FIG. 4, a third conductive layer M3 may be provided or formed on the first conductive layer M1 and the second conductive layer M2 before forming the conductive pattern layer MP (shown in FIG. 5), wherein the third conductive layer M3 may be a seed layer, which may conduce to the subsequent formation of the conductive pattern layer MP and/or improve the adhesion between the layers. The manufacturing process of the third conductive layer M3 may include atomic layer deposition, physical vapor deposition, chemical vapor deposition, sputtering, coating, other suitable deposition processes or combinations of the above. In some embodiments, the third conductive layer M3 may be a composite layer, for example, composed of a first sub-layer M31 and a second sub-layer M32. Specifically, the first sub-layer M31 may be firstly formed on the upper surface SBa and the lower surface SBb of the substrate SB, the first conductive layer M1 and the second conductive layer M2 and filled in the space SP, so that the first sub-layer M31 is presented as covering the through hole VH in the cross-sectional view, that is, filling the upper and/or lower opening end of the through hole VH, and then the second sub-layer M32 is formed on the first sub-layer M31, so that the second sub-layer M32 is blanketly formed on the surface of the first sub-layer M31. The material of the first sub-layer M31 includes, for example, titanium (Ti), titanium nitride (TiN), ruthenium (Ru), tantalum (Ta), silver (Ag) or combinations of the above materials, and the material of the second sub-layer M32 includes, for example, copper (Cu). The functions of the first sub-layer M31 and the second sub-layer M32 may be referred to the first sub-layer M11 and the second sub-layer M12 described above, which will not be redundantly described herein. However, the structure of the third conductive layer M3 of the present disclosure is not limited to the above, and the third conductive layer M3 may be a single-layer structure or other suitable multi-layer structures in other embodiments. In some embodiments, the third conductive layer M3 and the first conductive layer M1 may include the same material. For example, the material of the first sub-layer M31 is the same as that of the first sub-layer M11, and/or the material of the second sub-layer M32 is the same as that of the second sub-layer M12, but not limited herein.

As shown in FIG. 4, a photoresist layer PR including photoresist patterns may be formed on the third conductive layer M3 after the third conductive layer M3 is formed, wherein the photoresist layer PR is not overlapped with the through hole VH in the direction Y. For example, a plurality of photoresist patterns PR1 may be formed on the third conductive layer M3 located on the upper surface SBa of the substrate SB, and a plurality of photoresist patterns PR2 may be formed on the third conductive layer M3 located on the lower surface SBb of the substrate SB. According to the fan-out circuit design of the electronic device, the photoresist patterns PR1 and the photoresist patterns PR2 may respectively expose a portion of the third conductive layer M3, so that the photoresist patterns PR1 and the photoresist patterns PR2 are symmetrically or asymmetrically disposed on the upper side and the lower side of the substrate SB. For example, the photoresist patterns PR1 located at the upper side of the substrate SB and the photoresist patterns PR2 located at the lower side of the substrate SB may be manufactured at the same time to be symmetrically disposed, or the photoresist patterns PR1 and the photoresist patterns PR2 may be manufactured by different steps to be asymmetrically disposed. In a cross-sectional view, side walls PRS of the photoresist pattern PR1 and the photoresist pattern PR2 may be inclined surfaces, and the pattern widths thereof may gradually increase as approaching the surface of the third conductive layer M3.

As shown in FIG. 5, the conductive pattern layer MP may be formed on the third conductive layer M3 after the photoresist layer PR shown in FIG. 4 is formed. Specifically, the conductive pattern layers MP may be formed on the third conductive layer M3 which is not covered by the photoresist patterns PR1 and the photoresist patterns PR2 at the upper and lower sides of the substrate SB, respectively. For example, the conductive pattern layer MP may be formed by the electroplating process or the electroless plating process. Then, the photoresist layer PR may be removed by the etching process, and a portion of the third conductive layer M3 corresponding to the photoresist patterns PR1 and the photoresist patterns PR2 (for example, overlapped with the photoresist patterns PR1 and the photoresist patterns PR2 in the direction Y or located between the photoresist layer PR and the substrate SB) may be removed, thus forming a connection stacking structure CS as shown in FIG. 5, which may be applied to an electronic device as a portion of the layer-stacking structure of the electronic device. The material of the conductive pattern layer MP includes, for example, copper (Cu), titanium (Ti), aluminum (Al), molybdenum (Mo), nickel (Ni), ruthenium (Ru), tantalum (Ta), tungsten (W), other suitable conductive materials or combinations of the above materials. In some embodiments, the conductive pattern layer MP and the second conductive layer M2 may include the same material, but not limited herein. The forming method of the conductive pattern layer MP may be different from that of the first sub-layer M31 and the second sub-layer M32 of the third conductive layer M3, so that the crystallinity, the grain size and a thickness T2 in the direction Y of the formed conductive pattern layer MP may be greater than the crystallinity, the grain size and a thickness T3 in the direction Y of the second sub-layer M32. For example, the thickness T2 of the conductive pattern layer MP may be greater than or equal to 0.5 micrometers and less than or equal to 30 micrometers, and the thickness T3 of the second sub-layer M32 is less than or equal to 0.3 micrometers, but not limited herein.

The connection stacking structure CS of the electronic device formed by the above manufacturing method shown in FIG. 2 to FIG. 5 may include the substrate SB having the through hole VH, a conductive pattern layer MIP (which may be referred to as a first conductive pattern layer) formed by the first conductive layer M1, a conductive pattern layer M2P (which may be referred to as a second conductive pattern layer) formed by the second conductive layer M2, a conductive pattern layer M3P (which may be referred to as a third conductive pattern layer) formed by the third conductive layer M3, and the conductive pattern layer MP (which may be referred to as a fourth conductive pattern layer). According to the embodiment shown in FIG. 5, in a cross-sectional view, the width of the conductive pattern layer MP may gradually decrease as approaching the surface of the conductive pattern layer M3P. Specifically, an included angle θ1 between a sidewall extension line MPS_L of a side wall MPS of the conductive pattern layer MP and the direction Y may be greater than or equal to 10 degrees and less than or equal to 50 degrees. In addition, an included angle θ2 between the side wall MPS of the conductive pattern layer MP and a bottom surface MPB thereof may be greater than or equal to 80 degrees and less than or equal to 120 degrees.

As shown in FIG. 5, the side wall MPS of the conductive pattern layer MP may protrude from the side wall VHS of the through hole VH by a distance L1 in the direction X, wherein the distance L1 may be greater than or equal to 5 times of a thickness of the conductive pattern layer M3P in the direction Y and less than or equal to 20 times of the above thickness. In a cross-sectional view, the distance L1 may be obtained by measuring the minimum distance between the side wall VHS at one side (e.g., the right side) of the through hole VH to the side wall MPS at the same side (e.g., the right side) of the conductive pattern layer MP along the direction X. In some embodiments, the first sub-layer M31 of the conductive pattern layer M3P may have a thickness T4 in the direction Y, and the distance L1 may be greater than or equal to 5 times of the thickness T4 and less than or equal to 20 times of the thickness T4 (i.e., T4*5≤L1<T4*20). Through the structural design that the distance L1 is within a specific range, the conductive pattern layer MP may not be easily peeled off, so as to improve the adhesion thereof.

According to the embodiment of the present disclosure, the formed conductive pattern layer M3P and the conductive pattern layer MP may be used to form a portion of a redistribution structure of an electronic device (e.g., a portion of the redistribution structure RST of an electronic device ED shown in FIG. 6). That is to say, the redistribution structure may be disposed on the conductive pattern layer MIP and the conductive pattern layer M2P, and the redistribution structure includes the conductive pattern layer M3P and the conductive pattern layer MP. The redistribution structure may be electrically connected to a chip or an electronic unit through bonding pads or other bonding elements. Furthermore, the redistribution structure may include at least one conductive layer and at least one insulating layer, so as to redistribute the circuit and/or further increase the fan-out area of the circuit, or different electronic units may be electrically connected with each other through the redistribution structure. Alternatively, the redistribution structure may be a substrate used as an electrical interface with wiring between one circuit and another circuit. The purpose of the redistribution structure is to extend the connecting line to a wider pitch or redistribute the connecting line to another connecting line with a different pitch.

According to the embodiment shown in FIG. 5, the manufactured electronic device may include the substrate SB, the conductive pattern layer MIP, the conductive pattern layer M2P, the conductive pattern layer M3P and the conductive pattern layer MP. The substrate SB has a the upper surface SBa, the lower surface SBb and the through hole VH, wherein the side wall VHS of the through hole VH is connected with the upper surface SBa and the lower surface SBb. The conductive pattern layer MIP is disposed on the side wall VHS, the conductive pattern layer M2P is disposed on the conductive pattern layer MIP, the conductive pattern layer M3P is disposed on the conductive pattern layer MIP and the conductive pattern layer M2P, and the conductive pattern layer MP may be disposed on the conductive pattern layer M3P and the substrate SB. In the direction Y, the maximum height difference D1 (shown in FIG. 3) between the upper surface SBa of the substrate SB and the upper surface of the conductive pattern layer M2P (i.e., the upper surface M2a of the second conductive layer M2 shown in FIG. 3) is greater than or equal to 0.1 micrometers and less than or equal to 20 micrometers. According to the embodiment shown in FIG. 5, a portion of the conductive pattern layer M3P may be disposed in the space SP (shown in FIG. 3) between the side wall VH of the through hole VHS and the conductive pattern layer M2P. In some embodiments, as shown in FIG. 5, the electronic device may further include the buffer layer BF disposed between the conductive pattern layer MIP and the side wall VHS of the through hole VH. The detailed structures and materials of the layers and the elements of the electronic device described above may be referred to the above-mentioned embodiments, which will not be redundantly described herein.

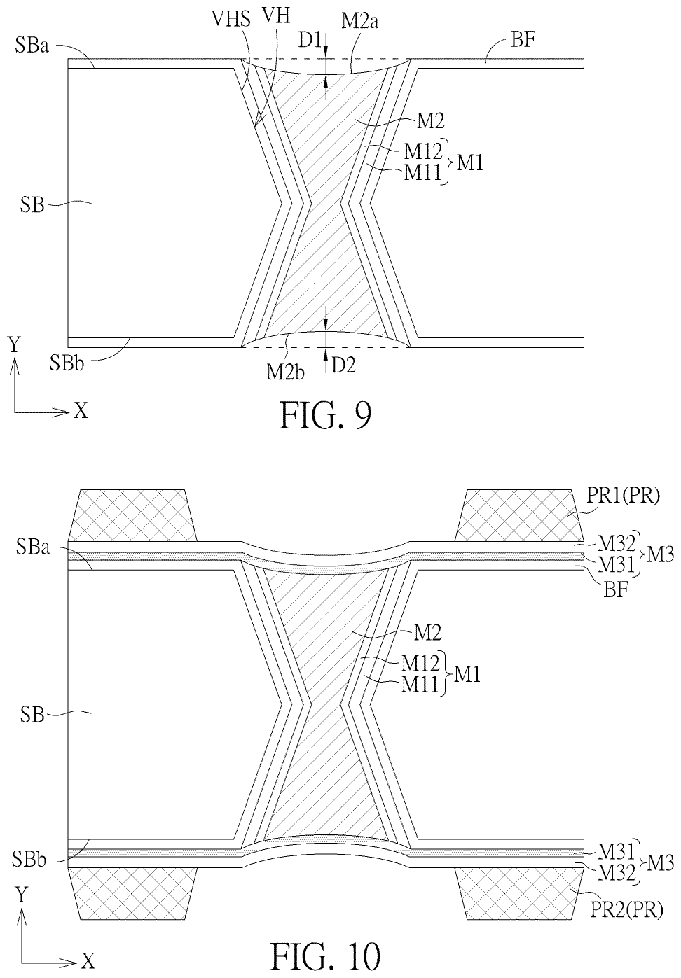

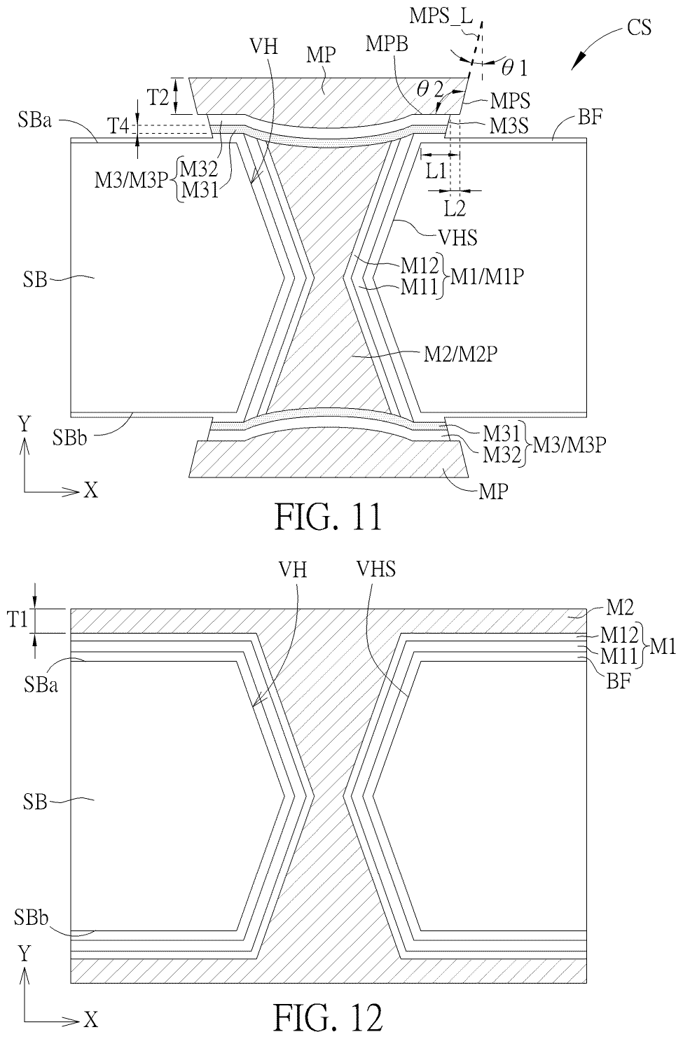

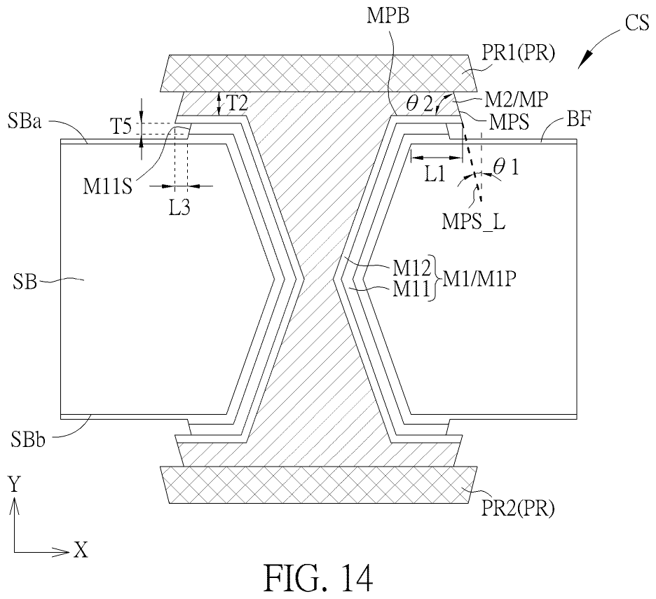

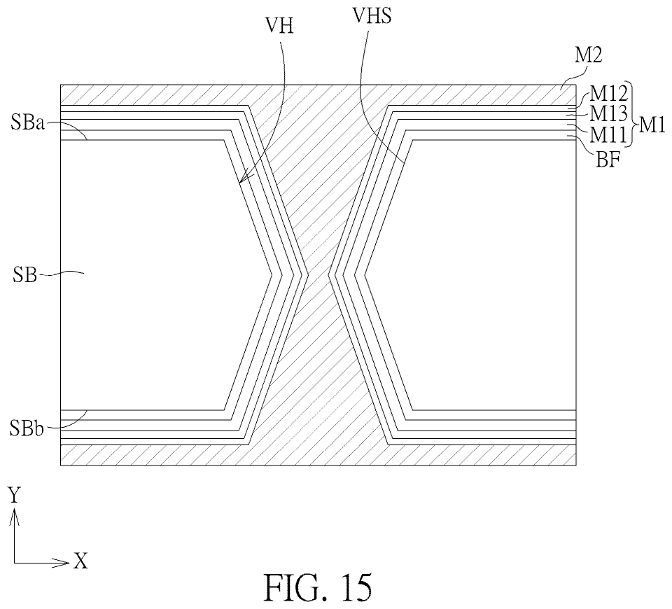

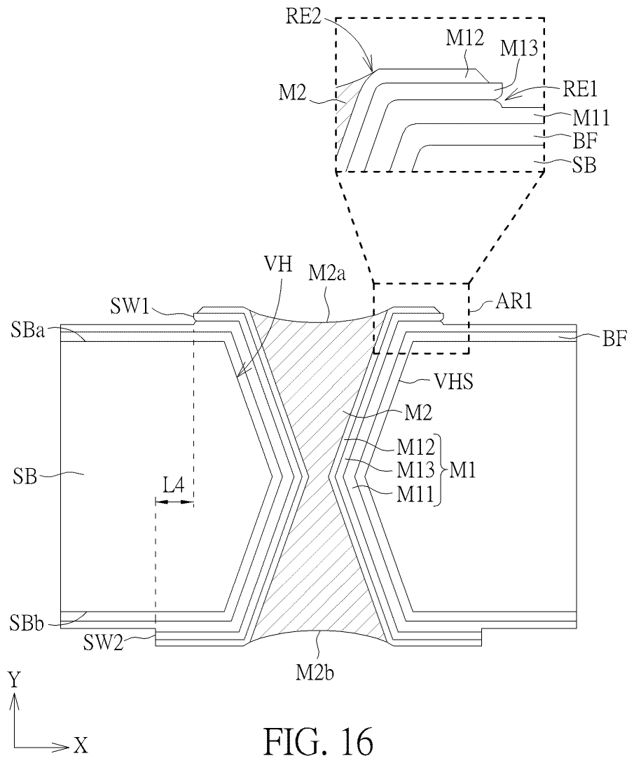

Please refer to FIG. 6, which is a cross-sectional schematic diagram of an electronic device according to an embodiment of the present disclosure. The manufacturing process of a region AR in the electronic device ED shown in FIG. 6 may correspond to the above manufacturing method shown in FIG. 2 to FIG. 5 or the manufacturing method shown in FIG. 9 to FIG. 11, FIG. 12 to FIG. 14, or FIG. 15 to FIG. 16. The electronic device ED shown in FIG. 6 is merely an example, and the structure of the electronic device of the present disclosure is not limited herein. As shown in FIG. 6, and in conjunction with FIG. 5 (or FIG. 11, FIG. 14 or FIG. 16), the conductive pattern layer MP disposed on the substrate SB may be used to form a portion of the redistribution structure RST of the electronic device ED. Specifically, the redistribution structure RST may be disposed on the substrate SB, and the redistribution structure RST may include at least one conductive layer (e.g., the conductive pattern layer MP and one or more conductive layers CL) and at least one insulating layer (e.g., one or more insulating layers IL). Each insulating layer IL may have at least one through hole, so that the conductive pattern layer MP may be electrically connected to the conductive layer(s) CL in the stacking direction. The conductive layer CL farthest from the substrate SB may include a plurality of connection pads for bonding with an electronic unit EU or other suitable elements. The stacking direction referred to in the present disclosure may be the direction Y. One or more electronic units EU may be disposed on the redistribution structure RST and bonded to the redistribution structure RST through bonding elements CE1, so that the electronic units EU may be electrically connected to other elements through the conductive layer CL, the conductive pattern layer MP and the conductive pattern layer M2P in the substrate SB, for example, further electrically connected to a circuit board CE through bonding elements CE2 disposed on one side of the substrate SB opposite to the redistribution structure RST. The bonding elements CE1 and the bonding elements CE2 may include, for example, solder balls, nickel, gold, copper, gallium or other suitable conductive materials. The insulating layer IL may include, for example, polyimide (PI), photosensitive polyimide (PSPI), Ajinomoto build-up film (ABF), silicon oxide (SiOx), silicon nitride (SiNx), silicon oxide nitride (SiOxNy) or other suitable dielectric materials. The conductive layer CL may include conductive material, including, for example, copper (Cu), titanium (Ti), aluminum (Al), molybdenum (Mo), nickel (Ni), ruthenium (Ru), tantalum (Ta), tungsten (W), nitride, carbide, other conductive materials or any combination of the above, but not limited herein.

According to the embodiment shown in FIG. 6, the electronic device ED may further include a protective layer PRL surrounding the substrate SB, the redistribution structure RST and the electronic units EU, so as to isolate moisture and air and/or reduce the damage of the electronic unit EU. The protective layer PRL may include, organic resin, epoxy, epoxy molding compound (EMC), ceramics, poly(methyl methacrylate) (PMMA), polydimethylsiloxane (PDMS), other suitable materials or combinations of the above materials, but not limited herein. In some embodiments, the electronic device ED may further include a filling layer FL1 and a filling layer FL2. The filling layer FL1 may be disposed between the electronic unit(s) EU and the redistribution structure RST to surround and protect the bonding elements CE1, and the filling layer FL2 may be disposed between the substrate SB and the circuit board CB to surround and protect the bonding elements CE2, and may be used as a buffer layer, but not limited herein.

Some embodiments of the manufacturing method of the electronic device and the manufactured electronic devices of the present disclosure will be detailed in the following. In order to simplify the illustration, the same elements in the following would be labeled with the same symbols. The differences between different embodiments are described in detail below, and the same features would not be described redundantly.

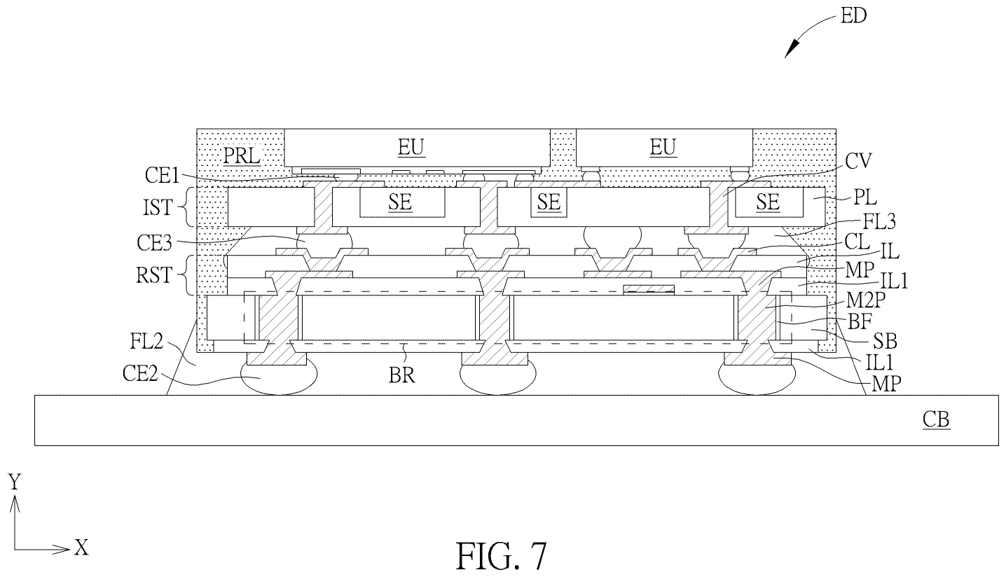

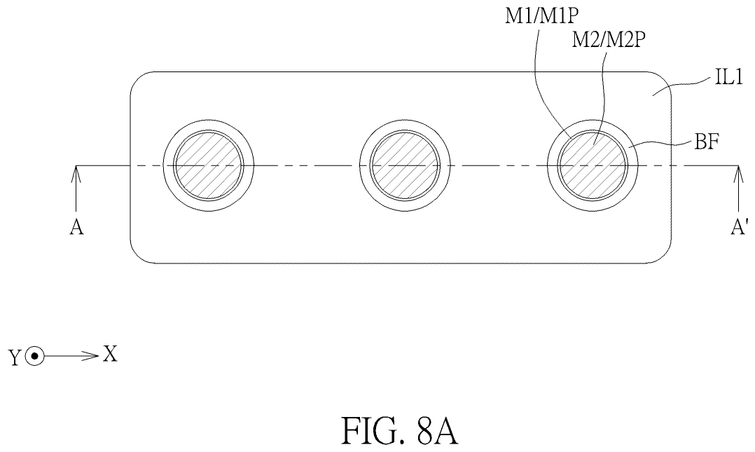

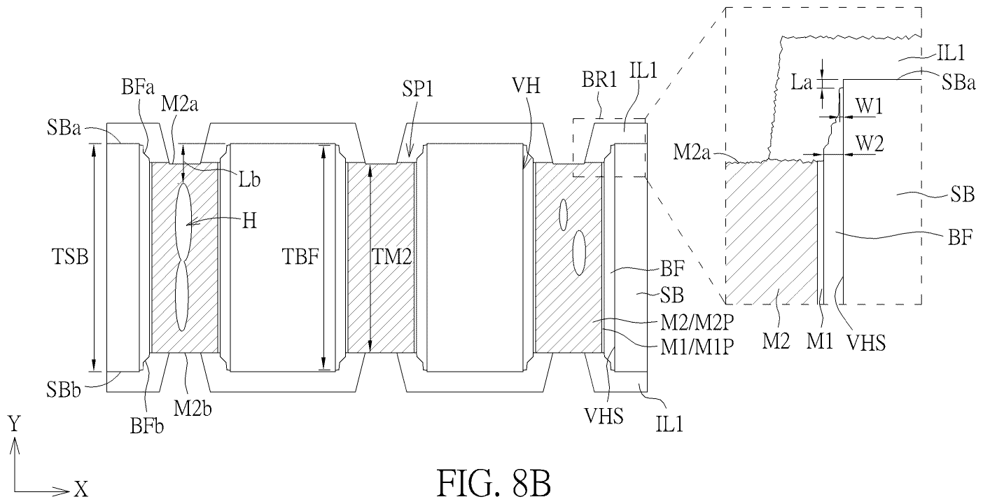

Please refer to FIG. 7, FIG. 8A and FIG. 8B. FIG. 7 is a cross-sectional schematic diagram of an electronic device according to another embodiment of the present disclosure. FIG. 8A is a top-view perspective schematic diagram illustrating a partial process of an electronic device according to another embodiment of the present disclosure. FIG. 8B is a cross-sectional schematic diagram illustrating the partial process of the electronic device of FIG. 8A, wherein FIG. 8B may be a cross-sectional schematic diagram corresponding to the section line A-A′ of FIG. 8A, and in order to simplify the drawing, the top-view perspective diagram of FIG. 8A only shows a portion of the elements/layer structures shown in FIG. 8B. A portion of the process of a region BR in the electronic device ED shown in FIG. 7 may correspond to the schematic diagrams illustrating the portion of the process shown in FIG. 8A and FIG. 8B, and the right part of FIG. 8B shows an enlarged schematic diagram of a region BRI in the cross-sectional view at the left part thereof. According to the embodiment shown in FIG. 7, FIG. 8A and FIG. 8B, after the inspection step (i.e., Step S150) is performed to obtain the first inspection result, it may be determined whether to form an insulating layer IL1 on the second conductive layer M2 according to the first inspection result. Specifically, when the first inspection result is confirmed to be acceptable, that is, when the first detection result meets the standard and the formed structure is confirmed to be acceptable, the insulating layer IL1 may be provided or formed on the second conductive layer M2. As shown in FIG. 8B, after removing a portion of the second conductive layer M2, a portion of the first conductive layer M1 and a portion of the buffer layer BF through the thinning step (i.e. Step S140) and before forming the insulating layer IL1, a surface treatment step may be further performed to roughen the surfaces of the buffer layer BF and the second conductive layer M2. For example, the upper surface BFa and the lower surface BFb of the buffer layer BF and the upper surface M2a and the lower surface M2b of the second conductive layer M2 may be roughened. The surface roughness (Rz) of the buffer layer BF may be greater than or equal to 0.05 micrometers and less than or equal to 1.5 micrometers, or greater than or equal to 0.1 micrometers and less than or equal to 0.8 micrometers, and the surface roughness (Rz) of the second conductive layer M2 can be greater than or equal to 0.1 micrometers and less than or equal to 3 micrometers. Through the above design, the adhesion between the buffer layer BF, the second conductive layer M2 and the insulating layer IL1 may be enhanced, but not limited herein.

As shown in the cross-sectional view at the right part of FIG. 8B, in the direction X, a width W1 of a portion of the buffer layer BF closest to the upper surface SBa of the substrate SB may be less than a width W2 of a portion of the buffer layer BF closest to the upper surface M2a of the second conductive layer M2. For example, the width of the buffer layer BF may gradually increase in the direction from the position adjacent to the upper surface SBa to the position away from the upper surface SBa. In addition, a distance La may exist between the upper surface SBa of the substrate SB and the top of the buffer layer BF in the direction Y, i.e., a portion of the side wall VHS of the through hole VH of the substrate SB may be exposed without being covered by the buffer layer BF, thereby enhancing the adhesion between the layers. The above distance La may be greater than or equal to 0.1 micrometers and less than or equal to 10 micrometers. In some embodiments, the portion of the buffer layer BF close to the lower surface SBb of the substrate SB may also have the same structure as that is described above, but not limited herein. A patterning step may be performed on the insulating layer IL1 to expose a portion of the second conductive layer M2 after the insulating layer IL1 is formed, so as to facilitate the formation of subsequent circuit structure. As shown in FIG. 7, the conductive pattern layer MP may be formed on the insulating layer IL1 and the exposed second conductive layer M2. In some embodiments, a surface treatment step may be performed on the insulating layer IL1 to roughen the surface thereof, so as to enhance the adhesion between the insulating layer IL1 and the conductive pattern layer MP formed thereon, wherein the surface roughness (Rz) of the insulating layer IL1 may be greater than or equal to 0.1 micrometers and less than or equal to 5 micrometers. The surface treatment referred to in the present disclosure may include dry etching, wet etching, plasma treatment or combinations of the above, so as to increase the surface roughness or improve the impedance, but not limited herein.

As shown in FIG. 7, FIG. 8A and FIG. 8B, according to the electronic device ED of an embodiment manufactured by the manufacturing method described above, the redistribution structure RST disposed on the substrate SB may include an insulating layer IL1, and a portion of the insulating layer IL1 may be disposed in a space SP1 between the side wall VHS of the through hole VH and the conductive pattern layer M2P formed by the second conductive layer M2. Furthermore, as shown in FIG. 8B, the electronic device ED may further include a buffer layer BF disposed between the side wall VHS of the through hole VH and the conductive pattern layer MIP formed by the first conductive layer M1, and a portion of the buffer layer BF may be in contact with the portion of the insulating layer IL1 disposed in the space SP1. That is to say, within the through hole VH, the insulating layer IL1 may be in contact with the surfaces of the conductive pattern layer M2P and the buffer layer BF to enhance the adhesion between the layers. In some embodiments, as shown in FIG. 8B, a volume ratio of the conductive pattern layer M2P in the through hole VH may be greater than or equal to 75% and less than or equal to 98%, i.e., the through hole VH may not be totally filled up with the conductive pattern layer M2P, so that the conductive pattern layer M2P located in the through hole VH may occupy 75% to 98% of the accommodating space of the through hole VH, so as to relieve stress and reduce the risk of substrate cracking. In some embodiments, the conductive pattern layer M2P may have one or more holes H, and the material filled in the hole H may be different from the material of the conductive pattern layer M2P, but not limited herein. A distance Lb may exist between the hole H and the upper surface SBa of the substrate SB in the direction Y. For example, the above distance Lb may be obtained by measuring the shortest distance between the upper surface SBa and the top of the hole H along the direction Y in a cross-sectional view, wherein the distance Lb can be greater than or equal to 10 micrometers. That is to say, the hole H should be wrapped in the conductive pattern layer M2P, or the hole H has a first volume V1, and the conductive pattern layer M2P surrounding the hole H has a second volume V2, wherein a ratio of the first volume V1 to the second volume V2 should be less than or equal to 0.05, so as to reduce the stress influence, but not limited herein. Referring to FIG. 8B, the substrate SB may have a substrate thickness TSB, the conductive pattern layer M2P may have a conductive pattern layer thickness TM2, and the buffer layer BF may have a buffer layer thickness TBF, wherein a ratio of the substrate thickness TSB to the conductive pattern layer thickness TM2 may be greater than or equal to 1.01 and less than or equal to 1.2 (i.e., 1.01≤TSB/TM2≤1.2), and a ratio of the substrate thickness TSB to the buffer layer thickness TBF may be greater than or equal to 1.002 and less than or equal to 1.15 (i.e., 1.002≤TSB/TBF≤1.15).

According to the embodiments shown in FIG. 7, the redistribution structure RST of the electronic device ED may further include the conductive pattern layer MP disposed in the through hole of the insulating layer IL1 and on the insulating layer IL1, and the redistribution structure RST may further include one or more conductive layers CL and one or more insulating layers IL stacked on the insulating layer IL1 and the conductive pattern layer MP. Each insulating layer IL may have at least one through hole, so that the conductive pattern layer MP may be electrically connected to the conductive layer(s) CL in the stacking direction. The electronic device ED may further include an interposer structure IST disposed between the substrate SB and the electronic unit(s) EU. As shown in FIG. 7, the interposer structure IST may be disposed between the redistribution structure RST and the electronic unit EU in the direction Y. The interposer structure IST may include an interposer PL and at least one auxiliary element SE, and the interposer PL may surround the auxiliary element SE, wherein the interposer PL may include organic material or inorganic material, and the auxiliary element SE may include an active element or a passive element. The electronic unit EU may be electrically connected to one or more auxiliary elements SE, and the electronic unit EU may be electrically connected to the substrate SB through the interposer structure IST. As shown in FIG. 7, the interposer structure IST may include a plurality of conductive structures CV, wherein the conductive structures CV may be formed by, for example, filling through holes penetrating the interposer PL with conductive material, and one or more electronic units EU may be bonded to the interposer structure IST through the bonding elements CE1 and electrically connected to the conductive structures CV, so that the electronic unit EU may be electrically connected to the circuit board CE through the conductive structures CV, the bonding elements CE3 disposed between the interposer structure IST and the redistribution structure RST, the conductive layers CL and the conductive pattern layer MP in the redistribution structure RST, the conductive pattern layer M2P in the substrate SB and the bonding elements CE2. In some embodiments, the electronic device ED may further include a filling layer FL3, and the filling layer FL3 may be disposed between the interposer structure IST and the redistribution structure RST to surround and protect the bonding elements CE3.

Please refer to FIG. 9 to FIG. 11, in conjunction with FIG. 1 and FIG. 2. FIG. 9 to FIG. 11 are schematic diagrams illustrating a portion of the process of a manufacturing method of an electronic device according to another embodiment of the present disclosure. As shown in FIG. 9, after the process step shown in FIG. 2 (i.e., after Step S130), Step S140 may be performed to perform a thinning step to remove a portion of the first conductive layer M1 and a portion of the second conductive layer M2, and to expose the buffer layer BF on the upper surface SBa and the lower surface SBb of the substrate SB. For example, the portion of the first conductive layer M1 and the portion of the second conductive layer M2 may be removed by the chemical mechanical polishing process and/or the wet etching process. In this embodiment, the buffer layer BF is not removed and still disposed on the surface of the substrate SB after the thinning step, so that the strength of the substrate SB may be increased. In addition, the portion of the first conductive layer M1 and the portion of the second conductive layer M2 are removed through the thinning step, so as to thin the layer-stacking structure on the substrate SB, such that the stress matching problem between the layers may be alleviated, thereby improving the yield and reliability of the electronic device.

According to the embodiment shown in FIG. 9, after removing the portion of the second conductive layer M2 through the thinning step (i.e., Step S140), in the direction Y, the maximum height difference D1 between the upper surface SBa of the substrate SB and the upper surface M2a of the second conductive layer M2 adjacent thereto may be greater than or equal to 0.1 micrometers and less than or equal to 20 micrometers, and the maximum height difference D2 between the lower surface SBb of the substrate SB and the lower surface M2b of the second conductive layer M2 adjacent thereto may be greater than or equal to 0.1 micrometers and less than or equal to 20 micrometers. As shown in FIG. 9, after removing the portion of the first conductive layer M1 and the portion of the second conductive layer M2 through the thinning step (i.e., Step S140), the upper surface M2a of the second conductive layer M2 and the upper surface of the first conductive layer M1 may jointly form a continuous or discontinuous concave surface, and the lower surface M2b of the second conductive layer M2 and the lower surface of the first conductive layer M1 may jointly form a continuous or discontinuous concave surface, but not limited herein.

After Step S140, Step S150 may be performed to perform an inspection step to obtain a first inspection result, and it may be determined whether to form a conductive pattern layer MP (shown in FIG. 11) on the second conductive layer M2 according to the first inspection result. Wherein, the first inspection result may include a thinned thickness T1 of the second conductive layer M2 on the upper surface SBa (or the lower surface SBb) of the substrate SB in the direction Y, and the step of forming the conductive pattern layer MP may be performed when the thinned thickness T1 is less than or equal to half of the original thickness T0 (shown in FIG. 2) (i.e., when T1≤T0*½). According to the embodiment shown in FIG. 9, the portion of the second conductive layer M2 on the upper surface SBa and the lower surface SBb of the substrate SB have been removed, i.e., the thinned thickness T1 of the second conductive layer M2 on the upper surface SBa (or the lower surface SBb) of the substrate SB is 0 (thus not labeled in FIG. 9), at this time the thinned thickness T1 is less than half of the original thickness T0, and it is determined to continue the processes of forming the conductive pattern layer MP as shown in FIG. 10 and FIG. 11 according to this inspection result. When the thinned thickness T1 is greater than half of the original thickness T0 (i.e., when T1>T0*½), another thinning step may be performed. In some embodiments, the first inspection result may further include whether the maximum height difference D1 (and/or the maximum height difference D2) being greater than or equal to 0.1 micrometers and less than or equal to 20 micrometers, but not limited herein.

When it is determined to continue to form the conductive pattern layer MP on the second conductive layer M2 according to the first inspection result, the following steps may be performed. As shown in FIG. 10, a third conductive layer M3 may be formed on the first conductive layer M1, the second conductive layer M2 and the buffer layer BF before forming the conductive pattern layer MP (shown in FIG. 11), wherein the third conductive layer M3 may be a seed layer. In some embodiments, the third conductive layer M3 may be a composite layer, for example, composed of a first sub-layer M31 and a second sub-layer M32. Specifically, the first sub-layer M31 may be firstly formed on the buffer layer BF located on the upper surface SBa and the lower surface SBb of the substrate SB, the first conductive layer M1 and the second conductive layer M2, so that the first sub-layer M31 is presented as covering the through hole VH or filling the opening ends of the through hole VH in the cross-sectional view, and then the second sub-layer M32 is formed on the first sub-layer M31, so that the second sub-layer M32 is blanketly formed on the surface of the first sub-layer M31. The materials of the first sub-layer M31 and the second sub-layer M32 may be referred to the aforementioned embodiments, which will not be redundantly described herein.

As shown in FIG. 10, a photoresist layer PR including photoresist patterns may be formed on the third conductive layer M3 after the third conductive layer M3 is formed, wherein the photoresist layer PR may be not overlapped with the through hole VH in the direction Y. For example, a plurality of photoresist patterns PR1 may be formed on the third conductive layer M3 located on the upper surface SBa of the substrate SB, and a plurality of photoresist patterns PR2 may be formed on the third conductive layer M3 located on the lower surface SBb of the substrate SB. According to the fan-out circuit design of the electronic device, the sizes and/or the distribution of the photoresist patterns PR1 and the photoresist patterns PR2 may be the same or different.

As shown in FIG. 11, the conductive pattern layer MP may be formed on the third conductive layer M3 after the photoresist layer PR shown in FIG. 10 is formed. For example, the conductive pattern layer MP may be formed by the electroplating process or the electroless plating process. Then, the photoresist layer PR may be removed by the etching process, and a portion of the third conductive layer M3 corresponding to the photoresist patterns PR1 and the photoresist patterns PR2 (for example, overlapped with the photoresist patterns PR1 and the photoresist patterns PR2 in the direction Y or located between the photoresist layer PR and the substrate SB) may be removed, thus forming a connection stacking structure CS as shown in FIG. 11, which may be applied to an electronic device as a portion of the layer-stacking structure of the electronic device. Because of the different etching rates of materials and/or using different etching solutions, a side wall M3S of the third conductive layer M3 may be recessed inward relative to a side wall MPS of the conductive pattern layer MP in the direction X after the above etching process, i.e., the side wall MPS of the conductive pattern layer MP may protrude from the side wall M3S of the third conductive layer M3 by a distance L2 in the direction X. The distance L2 may be greater than or equal to 100 nanometers and less than or equal to 1000 nanometers. In the manufacturing process of forming the redistribution structure, the insulating layer formed on the conductive pattern layer MP may be filled in the recess formed by the above distance L2, which may conduce to enhancing the adhesion between the layers. In a cross-sectional view, the distance L2 may be obtained by measuring the minimum distance between the side wall MPS at one side (e.g., the right side) of the conductive pattern layer MP to the side wall M3S at the same side (e.g., the right side) of the third conductive layer M3 along the direction X.

The connection stacking structure CS of the electronic device formed by the above manufacturing method shown in FIG. 2 and FIG. 9 to FIG. 11 may include the substrate SB having the through hole VH, a conductive pattern layer MIP formed by the first conductive layer M1, a conductive pattern layer M2P formed by the second conductive layer M2, a conductive pattern layer M3P formed by the third conductive layer M3, and the conductive pattern layer MP. According to the embodiment shown in FIG. 11, in a cross-sectional view, the width of the conductive pattern layer MP may gradually decrease as approaching the surface of the conductive pattern layer M3P. Specifically, an included angle θ1 between a sidewall extension line MPS_L of the side wall MPS of the conductive pattern layer MP and the direction Y may be greater than or equal to 10 degrees and less than or equal to 50 degrees. In addition, an included angle θ2 between the side wall MPS of the conductive pattern layer MP and a bottom surface MPB thereof may be greater than or equal to 80 degrees and less than or equal to 120 degrees.

As shown in FIG. 11, the side wall MPS of the conductive pattern layer MP may protrude from the side wall VHS of the through hole VH by a distance L1 in the direction X, wherein the distance L1 may be greater than or equal to 5 times of a thickness of the conductive pattern layer M3P in the direction Y and less than or equal to 20 times of the above thickness. In some embodiments, the first sub-layer M31 of the conductive pattern layer M3P may have a thickness T4 in the direction Y, and the distance L1 may be greater than or equal to 5 times of the thickness T4 and less than or equal to 20 times of the thickness T4 (i.e., T4*5≤L1≤T4*20). Through the structural design that the distance L1 is within a specific range, the conductive pattern layer MP may not be easily peeled off, so as to improve the adhesion thereof. In some embodiments, a thickness T2 of the conductive pattern layer MP in the direction Y may be greater than or equal to 0.5 micrometers and less than or equal to 30 micrometers, but not limited herein.

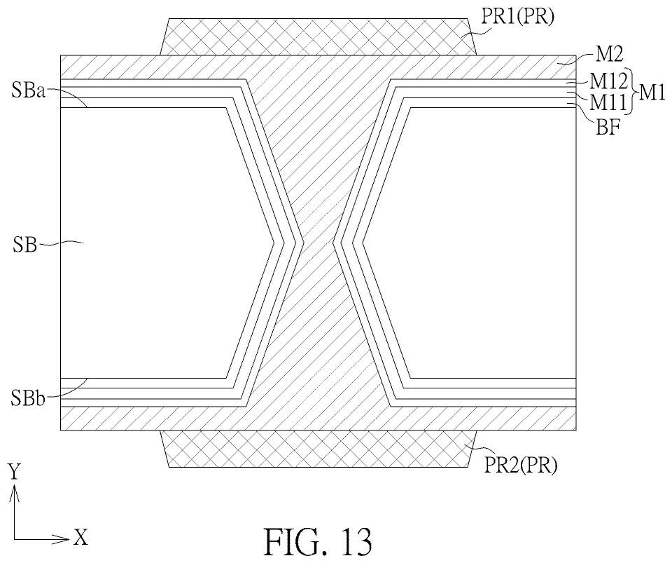

Please refer to FIG. 12 to FIG. 14, in conjunction with FIG. 1 and FIG. 2. FIG. 12 to FIG. 14 are schematic diagrams illustrating a portion of the process of a manufacturing method of an electronic device according to still another embodiment of the present disclosure. As shown in FIG. 12, after the process step shown in FIG. 2 (i.e., after Step S130), Step S140 may be performed to perform a thinning step to remove a portion of the second conductive layer M2, so that the thickness of the second conductive layer M2 in the direction Y is thinned from the original thickness T0 to a thinned thickness T1. After Step S140, Step S150 may be performed to perform an inspection step to obtain a first inspection result, and it may be determined whether to form a conductive pattern layer MP (shown in FIG. 14) on the second conductive layer M2 according to the first inspection result. Wherein, the first inspection result may include the thinned thickness T1 of the second conductive layer M2 on the upper surface SBa (or the lower surface SBb) of the substrate SB in the direction Y, and it may be determined to continue the process steps of forming the conductive pattern layer MP as shown in FIG. 13 and FIG. 14 when the thinned thickness T1 is less than or equal to half of the original thickness T0 (shown in FIG. 2) (i.e., when T1≤T0*½). When the thinned thickness T1 is greater than half of the original thickness T0 (i.e., when T1>T0*½), another thinning step may be performed. In this embodiment, the portion of the second conductive layer M2 is removed through the thinning step, so as to thin the layer-stacking structure on the substrate SB, such that the stress matching problem between the layers may be alleviated, thereby improving the yield and reliability of the electronic device.

When it is determined to continue to form the conductive pattern layer MP on the second conductive layer M2 according to the first inspection result, the following steps may be performed. As shown in FIG. 13, a photoresist layer PR including photoresist patterns may be formed on the second conductive layer M2, wherein the photoresist layer PR may be partially overlapped with the through hole VH in the direction Y. For example, a photoresist pattern PR1 may be formed on the second conductive layer M2 located on the upper surface SBa of the substrate SB, and a photoresist pattern PR2 may be formed on the second conductive layer M2 located on the lower surface SBb of the substrate SB. According to the fan-out circuit design of the electronic device, the sizes and/or the distribution of the photoresist pattern PR1 and the photoresist pattern PR2 may be the same or different.

As shown in FIG. 14, an etching process may be performed to form the conductive pattern layer MP after the photoresist layer PR shown in FIG. 13 is formed. Specifically, a portion of the second conductive layer M2 and a portion of the first conductive layer M1 that do not correspond to the photoresist pattern PR1 and the photoresist pattern PR2 (for example, that are not overlapped with the photoresist pattern PR1 and the photoresist pattern PR2 in the direction Y or are not located between the photoresist layer PR and the substrate SB) may be removed by the etching process, so as to form the conductive pattern layer MP and the conductive pattern layer M1P as shown in FIG. 14. In some embodiments, deviation may occur in the above etching process, so that the side walls of the second conductive layer M2 and the first conductive layer M1 are relatively recessed from the side walls of the photoresist pattern PR1 and the photoresist pattern PR2 after etching, but not limited herein. Then, the photoresist layer PR may be removed, thus forming a connection stacking structure CS, which may be applied to an electronic device as a portion of the layer-stacking structure of the electronic device. Because of the different etching rates of materials and/or using different etching solutions, a side wall M11S of the first sub-layer M11 of the conductive pattern layer MIP may be recessed inward relative to a side wall MPS of the conductive pattern layer MP in the direction X after the above etching process, i.e., the side wall MPS of the conductive pattern layer MP may protrude from the side wall M11S of the first sub-layer M11 by a distance L3 in the direction X. The distance L3 may be greater than or equal to 100 nanometers and less than or equal to 1000 nanometers. In the manufacturing process of forming the redistribution structure, the insulating layer formed on the conductive pattern layer MP may be filled in the recess formed by the above distance L3, which may conduce to enhancing the adhesion between the layers. In a cross-sectional view, the distance L3 may be obtained by measuring the minimum distance between the side wall MPS at one side (e.g., the left side) of the conductive pattern layer MP to the side wall M11S at the same side (e.g., the left side) of the first sub-layer M11 along the direction X. In some embodiments, after the above etching process, the buffer layer BF may be left on the upper surface SBa and the lower surface SBb of the substrate SB to increase the strength of the substrate SB.

The connection stacking structure CS of the electronic device formed by the above manufacturing method shown in FIG. 2 and FIG. 12 to FIG. 14 may include the substrate SB having the through hole VH, a conductive pattern layer MIP formed by the first conductive layer M1, and a conductive pattern layer MP formed by the second conductive layer M2. According to the embodiment shown in FIG. 14, in a cross-sectional view, the width of the conductive pattern layer MP may gradually increase as approaching the surface of the conductive pattern layer MIP. Specifically, an included angle θ1 between a sidewall extension line MPS_L of the side wall MPS of the conductive pattern layer MP and the direction Y may be greater than or equal to 10 degrees and less than or equal to 50 degrees. In addition, an included angle θ2 between the side wall MPS of the conductive pattern layer MP and a bottom surface MPB thereof may be greater than or equal to 35 degrees and less than or equal to 90 degrees.

As shown in FIG. 14, the side wall MPS of the conductive pattern layer MP may protrude from the side wall VHS of the through hole VH by a distance L1 in the direction X, wherein the distance L1 may be greater than or equal to 5 times of a thickness of the conductive pattern layer MIP in the direction Y and less than or equal to 20 times of the above thickness. In some embodiments, the first sub-layer M11 of the conductive pattern layer MIP may have a thickness T5 in the direction Y, and the distance L1 may be greater than or equal to 5 times of the thickness T5 and less than or equal to 20 times of the thickness T5 (i.e., T5*5≤L1≤T5*20). Through the structural design that the distance L1 is within a specific range, the conductive pattern layer MP may not be easily peeled off, so as to improve the adhesion thereof. In some embodiments, a thickness T2 of the conductive pattern layer MP in the direction Y may be greater than or equal to 0.5 micrometers and less than or equal to 30 micrometers, but not limited herein, wherein the thickness T2 may be equal to the thinned thickness T1 (shown in FIG. 12) of the second conductive layer M2.

Please refer to FIG. 15 and FIG. 16, in conjunction with FIG. 1. FIG. 15 and FIG. 16 are schematic diagrams illustrating a portion of the process of a manufacturing method of an electronic device according to yet another embodiment of the present disclosure, wherein the upper part of FIG. 16 shows an enlarged schematic diagram of a region ΔRI in the cross-sectional view at the lower part thereof. As shown in FIG. 15, first, Step S100 may be performed to provide a substrate SB, wherein the substrate SB has an upper surface SBa (which may be referred to as a first surface) and a lower surface SBb (which may be referred to as a second surface) opposite to the upper surface SBa. After Step S100, S110 may be performed to form a through hole VH penetrating the substrate SB, wherein a side wall VHS of the through hole VH is connected with the upper surface SBa and the lower surface SBb of the substrate SB. After Step S110, a buffer layer BF may be formed on the substrate SB to extend into the through hole VH, and then Step S120 may be performed to form a first conductive layer M1 on the substrate SB, and the first conductive layer M1 extends into the through hole VH, wherein the first conductive layer M1 may be a seed layer, which may conduce to the subsequent formation of a second conductive layer M2 and/or improve the adhesion between the layers.

According to the embodiment shown in FIG. 15, the first conductive layer M1 may be composed of a first sub-layer M1, a second sub-layer M12 and a third sub-layer M13. Specifically, the first sub-layer M11 may be formed on the upper surface SBa and the lower surface SBb of the substrate SB and the side wall VHS of the through hole VH. For example, the first sub-layer M11 may be blanketly formed on the surface of the buffer layer BF. Then, the third sub-layer M13 is formed on the first sub-layer M11 to extend into the through hole VH, and then the second sub-layer M12 is formed on the third sub-layer M13 to extend into the through hole VH, so that the first sub-layer M11, the third sub-layer M13 and the second sub-layer M12 are formed on the upper surface SBa and the lower surface SBb of the substrate SB and the side wall VHS of the through hole VH in sequence. The material of the first sub-layer M11 includes, for example, titanium (Ti), titanium nitride (TiN), ruthenium (Ru), tantalum (Ta) or combinations of the above materials. The first sub-layer M11 may conduce to improving the bonding strength between metal material and inorganic material, i.e., may improve the adhesion between the layers, and the first sub-layer M11 may further be used as a barrier layer to block electron migration. The material of the second sub-layer M12 includes, for example, copper (Cu). The second sub-layer M12 may facilitate the formation of the conductive layer thereon in the subsequent processes. The material of the third sub-layer M13 includes, for example, organic material or inorganic material, and the third sub-layer M13 may serve as a buffer layer. However, the structure of the first conductive layer M1 of the present disclosure is not limited to the above.

As shown in FIG. 15, after Step S120, Step S130 may be performed to form a second conductive layer M2 on the first conductive layer M1, and the second conductive layer M2 extends into the through hole VH. The material of the second conductive layer M2 includes, for example, copper (Cu), titanium (Ti), aluminum (Al), molybdenum (Mo), nickel (Ni), ruthenium (Ru), tantalum (Ta), tungsten (W), other suitable conductive materials or combinations of the above materials.

As shown in FIG. 16, after Step S130, Step S140 may be performed to perform a thinning step to remove a portion of the second conductive layer M2 and a portion of the first conductive layer M1. Specifically, a portion of the second conductive layer M2, a portion of the second sub-layer M12 and a portion of the third sub-layer M13 may be removed by the chemical mechanical polishing process and/or the wet etching process to expose a portion of the first sub-layer M11 located on the upper surface SBa and the lower surface SBb of the substrate SB, thus forming a layer-stacking structure as shown in FIG. 16, which may be applied to an electronic device as a portion of the layer-stacking structure of the electronic device. Because of the different etching rates of materials and/or using different etching solutions, after the above etching process, a recess RE1 may be formed at the boundary of the first sub-layer M11 and the third sub-layer M13, and a recess RE2 may be formed at the boundary of the second conductive layer M2 and the second sub-layer M12. The insulating layer formed on the first conductive layer M1 and the second conductive layer M2 may be filled in the recess RE1 and the recess RE2, which may conduce to enhancing the adhesion between the layers. In some embodiments, the recess depth of the recess RE1 and the recess RE2 may be less than or equal to 0.3 micrometers to reduce the probability of layer being peeled off, but not limited herein. In this embodiment, the portion of the second conductive layer M2 and the portion of the first conductive layer M1 are removed through the thinning step, so as to thin the layer-stacking structure on the substrate SB, such that the stress matching problem between the layers may be alleviated, thereby improving the yield and reliability of the electronic device.

According to the embodiment shown in FIG. 16, the upper surface M2a and the lower surface M2b of the second conductive layer M2 may be respectively recessed relative to the surfaces of the second sub-layer M12 to form recesses, i.e., the upper surface M2a and the lower surface M2b of the second conductive layer M2 may be respectively recessed toward the upper surface SBa and the lower surface SBb of the substrate SB in the direction Y, and the upper surface M2a and the lower surface M2b may be concave surfaces, for example. In some embodiments, in the direction X, a distance L4 may exist between a side wall SW1 of the third sub-layer M13 located on the upper surface SBa of the substrate SB and a side wall SW2 of the third sub-layer M13 located on the lower surface SBb of the substrate SB, i.e., the layer structures on the upper side and the lower side of the substrate SB may be disposed asymmetrically. In a cross-sectional view, the distance L4 may be obtained by measuring the minimum distance between the side wall SW1 at one side (e.g., the left side) of the third sub-layer M13 located on the upper surface SBa to the side wall SW2 at the same side (e.g., the left side) of the third sub-layer M13 located on the lower surface SBb along the direction X, wherein the distance L4 may be greater than or equal to 1 micrometer and less than or equal to 10 micrometers.

From the above description, according to the manufacturing method of the electronic device and the manufactured electronic device of the embodiments of the present disclosure, by performing the thinning step during the manufacturing process to remove at least a portion of the conductive layer formed on the substrate, the stress matching problem between the layers may be alleviated, thereby improving the yield and reliability of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a substrate, wherein the substrate has a first surface and a second surface opposite to the first surface;
forming a through hole penetrating the substrate, wherein a side wall of the through hole is connected with the first surface and the second surface;
providing a first conductive layer on the substrate, wherein the first conductive layer extends into the through hole;
providing a second conductive layer on the first conductive layer, wherein the second conductive layer extends into the through hole, and the second conductive layer has an original thickness;
performing a thinning step to remove at least a portion of the second conductive layer; and
performing an inspection step to obtain a first inspection result, and determining whether to continue subsequent steps according to the first inspection result.

2. The manufacturing method of the electronic device according to claim 1, wherein the first inspection result comprises a thinned thickness of the second conductive layer on the first surface, and the manufacturing method of the electronic device further comprises forming a conductive pattern layer on the second conductive layer when the thinned thickness is less than or equal to half of the original thickness.

3. The manufacturing method of the electronic device according to claim 2, wherein the second conductive layer has a third surface adjacent to the first surface, and the first inspection result further comprises a maximum height difference between the first surface and the third surface in a normal direction of the substrate greater than or equal to 0.1 micrometers and less than or equal to 20 micrometers.

4. The manufacturing method of the electronic device according to claim 2, further comprising performing another thinning step when the thinned thickness is greater than half of the original thickness.

5. The manufacturing method of the electronic device according to claim 2, wherein an included angle between a sidewall extension line of the conductive pattern layer and a normal direction of the substrate is greater than or equal to 10 degrees and less than or equal to 50 degrees.

6. The manufacturing method of the electronic device according to claim 2, wherein the thinning step further comprises removing a portion of the first conductive layer.

7. The manufacturing method of the electronic device according to claim 6, further comprising providing a third conductive layer on the first conductive layer and the second conductive layer before forming the conductive pattern layer.

8. The manufacturing method of the electronic device according to claim 7, wherein the third conductive layer and the first conductive layer comprise a same material.

9. The manufacturing method of the electronic device according to claim 2, wherein the conductive pattern layer and the second conductive layer comprise a same material.

10. The manufacturing method of the electronic device according to claim 1, further comprising providing an insulating layer on the second conductive layer when the first inspection result is confirmed to be acceptable.

11. The manufacturing method of the electronic device according to claim 1, further comprising providing a buffer layer on the substrate before forming the first conductive layer,
wherein the thinning step further comprises removing a portion of the buffer layer, and a method of removing the portion of the buffer layer is different from a method of removing the portion of the second conductive layer.

12. The manufacturing method of the electronic device according to claim 11, wherein the buffer layer has a fourth surface adjacent to the first surface after the portion of the buffer layer is removed, wherein a maximum height difference between the first surface and the fourth surface in a normal direction of the substrate is greater than or equal to 0.5 micrometers and less than or equal to 20 micrometers.

13. An electronic device, comprising:
a substrate having a first surface, a second surface and a through hole, wherein a side wall of the through hole is connected with the first surface and the second surface;
a first conductive pattern layer disposed on the side wall;
a second conductive pattern layer disposed on the first conductive pattern layer; and
a redistribution structure disposed on the first conductive pattern layer and the second conductive pattern layer,
wherein the second conductive layer has a third surface adjacent to the first surface, and a maximum height difference between the first surface and the third surface in a normal direction of the substrate is greater than or equal to 0.1 micrometers and less than or equal to 20 micrometers.

14. The electronic device according to claim 13, wherein the redistribution structure comprises a third conductive pattern layer and a fourth conductive pattern layer, a portion of the third conductive pattern layer is disposed in a space between the side wall of the through hole and the second conductive pattern layer, and the fourth conductive pattern layer is disposed on the third conductive pattern layer and the substrate.

15. The electronic device according to claim 14, wherein the third conductive pattern layer has a thickness, and a side wall of the fourth conductive pattern layer protrudes from the side wall of the through hole by a distance in a direction, wherein the distance is greater than or equal to 5 times of the thickness and less than or equal to 20 times of the thickness.

16. The electronic device according to claim 13, further comprising a buffer layer disposed between the first conductive pattern layer and the side wall of the through hole, wherein the buffer layer has a fourth surface adjacent to the first surface, and a maximum height difference between the first surface and the fourth surface in a normal direction of the substrate is greater than or equal to 0.5 micrometers and less than or equal to 20 micrometers.

17. The electronic device according to claim 13, wherein the redistribution structure comprises an insulating layer, and a portion of the insulating layer is disposed in a space between the side wall of the through hole and the second conductive pattern layer.

18. The electronic device according to claim 17, further comprising a buffer layer disposed between the side wall of the through hole and the first conductive pattern layer, wherein a portion of the buffer layer is in contact with the portion of the insulating layer.

19. The electronic device according to claim 18, wherein the buffer layer has a surface roughness greater than or equal to 0.05 micrometers and less than or equal to 1.5 micrometers.

20. The electronic device according to claim 13, wherein a volume ratio of the second conductive pattern layer in the through hole is greater than or equal to 75% and less than or equal to 98%.
